(19) United States
(12) Patent Application Publication
(10) Pub. No.: US 2026/0163548 A1
(43) Pub. Date: Jun. 11, 2026

(54) FLEXIBLE SHARED REFLECTOR FOR SURFACE ACOUSTIC WAVE FILTER

(71) Applicant: SKYWORKS SOLUTIONS, INC., Irvine, CA (US)

(72) Inventors: Joji Fujiwara, Suita-Shi (JP); Satoru Ikeuchi, Ashiya-Shi (JP); Satoshi Niwa, Taito-Ku (JP)

(21) Appl. No.: 19/181,570

(22) Filed: Apr. 17, 2025

Related U.S. Application Data
(60) Provisional application No. 63/639,238, filed on Apr. 26, 2024.

(51) Int. Cl. H03H 9/02; H03H 9/145; H03H 9/64

(52) U.S. Cl. CPC H03H 9/02637; H03H 9/145; H03H 9/6483

(57) ABSTRACT

Aspects and embodiments disclosed herein are generally directed to a surface acoustic wave device comprising a first surface acoustic wave resonator having a first aperture length and a first stack thickness, a second surface acoustic wave resonator having a second aperture length and a second stack thickness, one of the first aperture length and second aperture length being different, or the first stack thickness and the second stack thickness being different, and a common reflector shared by the first surface acoustic wave resonator and the second surface acoustic wave resonator.

### CROSS-REFERENCE TO RELATED APPLICATIONS

This application claims priority under 35 U.S.C. § 119(e) to U.S. Provisional Patent Application Ser. No. 63/639,238, titled “FLEXIBLE SHARED REFLECTOR FOR SURFACE ACOUSTIC WAVE FILTER,” filed Apr. 26, 2024, the entire content of which is incorporated herein by reference for all purposes.

### BACKGROUND

### Technical Field

Embodiments of this disclosure relate to acoustic wave devices and filters including same.

### Description of Related Technology

Acoustic wave devices, for example, surface acoustic wave (SAW) and bulk acoustic wave (BAW) devices may be utilized as components of filters in radio frequency electronic systems. For instance, filters in a radio frequency front-end of a mobile phone can include acoustic wave filters. Two acoustic wave filters can be arranged as a duplexer.

### SUMMARY

In accordance with one aspect, there is provided a surface acoustic wave device. The surface acoustic wave device comprises a first surface acoustic wave resonator having a first aperture length and a first stack thickness, a second surface acoustic wave resonator having a second aperture length and a second stack thickness, one of the first aperture length and second aperture length being different, or the first stack thickness and the second stack thickness being different, and a common reflector shared by the first surface acoustic wave resonator and the second surface acoustic wave resonator.

In some embodiments, lengthwise centers of the apertures of the first surface acoustic wave resonator and the second surface acoustic wave resonator are unaligned in a lengthwise direction.

In some embodiments, the common reflector overlaps entireties of the lengths of the apertures of the first surface acoustic wave resonator and the second surface acoustic wave resonator.

In some embodiments, the first aperture length and the second aperture length are different and the common reflector overlaps entireties of the lengths of the apertures of the first surface acoustic wave resonator and the second surface acoustic wave resonator.

In some embodiments, the first stack of the first surface acoustic wave resonator includes interdigital transducer electrodes covered by a first layer of SiO₂ having a first thickness and the second stack of the second surface acoustic wave resonator includes interdigital transducer electrodes covered by a second layer of SiO₂ having a second thickness different from the first thickness.

In some embodiments, the common reflector includes a first portion having the first SiO₂ layer thickness and a second portion having the second SiO₂ layer thickness.

In some embodiments, an interface between the first portion and the second portion is located at approximately a widthwise center of the common reflector.

In some embodiments, both the first aperture length and second aperture length are different, and the first stack thickness and the second stack thickness are different.

In some embodiments, the first surface acoustic wave resonator includes a first unshared reflector and the second surface acoustic wave device includes a second unshared reflector, a first reflector finger pitch of the first unshared reflector being different from a second reflector finger pitch of the second unshared reflector.

In some embodiments, the common reflector includes a first region having the first reflector finger pitch and a second region having the second reflector finger pitch.

In some embodiments, the common reflector includes a third region having a third reflector finger pitch that is between the first reflector finger pitch and the second reflector finger pitch.

In some embodiments, the first surface acoustic wave resonator and the second acoustic wave resonator are included in a ladder filter.

In some embodiments, one of the first surface acoustic wave resonator and the second acoustic wave resonator is a series resonator of the ladder filter and the other of the first surface acoustic wave resonator and the second acoustic wave resonator is a parallel resonator of the ladder filter.

In some embodiments, each of the first surface acoustic wave resonator and the second acoustic wave resonator is a series resonator of the ladder filter.

In some embodiments, each of the first surface acoustic wave resonator and the second acoustic wave resonator is a parallel resonator of the ladder filter.

In some embodiments, the first aperture length and the second aperture length are the same, the first surface acoustic wave resonator includes an SiO₂ film with a first thickness, and the second surface acoustic wave resonator includes an SiO₂ film with a second thickness that is different from the first thickness.

In some embodiments, the first aperture and the second aperture are aligned in a lengthwise direction.

In some embodiments, the first surface acoustic wave resonator and the second surface acoustic wave resonator include multilayer piezoelectric substrates.

In some embodiments, the multilayer piezoelectric substrate of the first surface acoustic wave resonator has one of a different SiO₂ thickness or a different piezoelectric material thickness than the multilayer piezoelectric substrate of the second surface acoustic wave resonator.

In some embodiments, the surface acoustic wave device is included in a radio frequency filter.

In some embodiments, the radio frequency filter is included in an electronics module.

In some embodiments, the electronics module is included in an electronic device.

### BRIEF DESCRIPTION OF THE DRAWINGS

Embodiments of this disclosure will now be described, by way of non-limiting example, with reference to the accompanying drawings.

FIG. 1A is a simplified plan view of an example of a surface acoustic wave resonator;

FIG. 1B is a simplified plan view of another example of a surface acoustic wave resonator;

FIG. 1C is a simplified plan view of another example of a surface acoustic wave resonator;

FIG. 2 is a cross-sectional view of a portion of an example of a surface acoustic wave resonator;

FIG. 3 is a cross-sectional view of a portion of an example of a temperature compensated surface acoustic wave resonator;

FIG. 4 is a schematic diagram of a radio frequency ladder filter;

FIG. 5A illustrates adjacent resonators with the same aperture lengths forming a portion of a ladder filter;

FIG. 5B illustrates how the adjacent resonators of FIG. 5A may be arranged to share a reflector;

FIG. 6A illustrates adjacent resonators with the different aperture lengths and different film stack heights forming a portion of a ladder filter;

FIG. 6B illustrates how the film stack heights of the resonator may differ due to different SiO₂ layer thicknesses;

FIG. 6C illustrates the resonators of FIG. 6A arranged with a shared reflector;

FIG. 6D illustrates another pair of adjacent resonators in a ladder filter with a shared reflector electrode;

FIG. 7 illustrates electrode pitches within resonators sharing a reflector and within the shared reflector;

FIG. 8 is a block diagram of one example of a filter module that can include one or more surface acoustic wave resonators according to aspects of the present disclosure;

FIG. 9 is a block diagram of one example of a front-end module that can include one or more filter modules according to aspects of the present disclosure; and

FIG. 10 is a block diagram of one example of a wireless device including the front-end module of FIG. 9.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

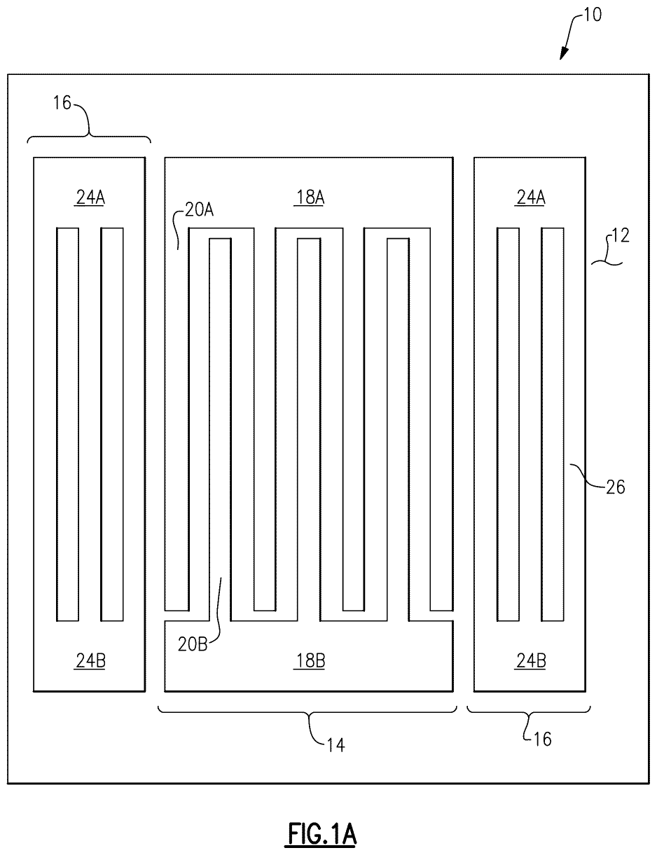

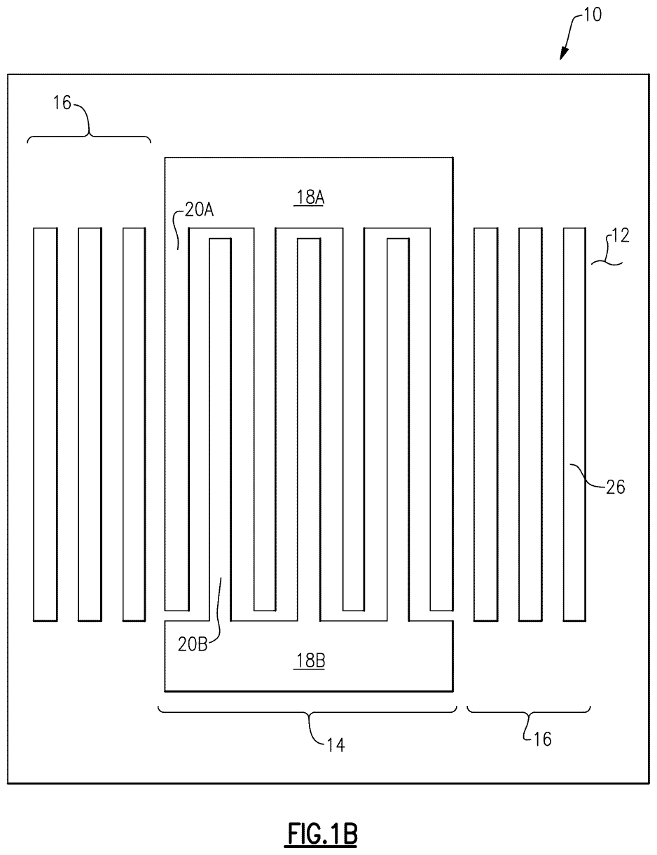

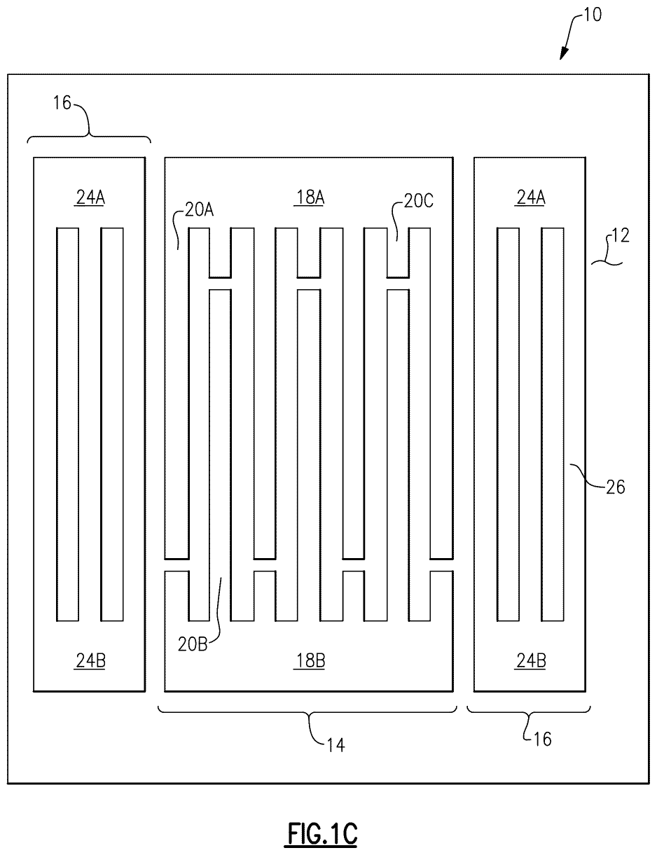

FIG. 1A is a plan view of a surface acoustic wave (SAW) resonator 10 such as might be used in a SAW filter, duplexer, balun, etc.

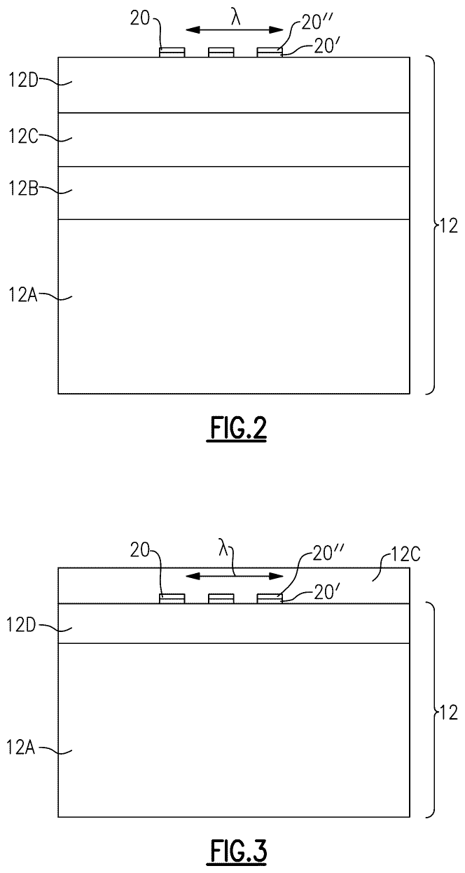

Acoustic wave resonator 10 is formed on a substrate 12 including a piezoelectric material layer, for example, a lithium tantalate (LiTaO₃) or lithium niobate (LiNbO₃) material layer. In some embodiments, as described with reference to FIG. 2 below, the substrate 12 may be a multilayer piezoelectric substrate (MPS). The acoustic wave resonator 10 includes Interdigital Transducer (IDT) electrodes 14 and reflector electrodes 16. In use, the IDT electrodes 14 excite a main acoustic wave having a wavelength λ along a surface of the substrate 12. The reflector electrodes 16 sandwich the IDT electrodes 14 and reflect the main acoustic wave back and forth through the IDT electrodes 14. The main acoustic wave of the device travels perpendicular to the lengthwise direction of the IDT electrodes.

The IDT electrodes 14 include a first bus bar electrode 18A and a second bus bar electrode 18B facing the first bus bar electrode 18A. The IDT electrodes 14 further include first electrode fingers 20A extending from the first bus bar electrode 18A toward the second bus bar electrode 18B, and second electrode fingers 20B extending from the second bus bar electrode 18B toward the first bus bar electrode 18A.

The reflector electrodes 16 (also referred to as reflector gratings or simply reflectors) each include a first reflector bus bar electrode 24A and a second reflector bus bar electrode 24B and reflector fingers 26 extending between and electrically coupling the first bus bar electrode 24A and the second bus bar electrode 24B.

In other embodiments disclosed herein, as illustrated in FIG. 1B, the reflector bus bar electrodes 24A, 24B may be omitted and the reflector fingers 26 may be electrically unconnected. Further, as illustrated in FIG. 1C, acoustic wave resonators as disclosed herein may include dummy electrode fingers 20C that are aligned with respective electrode fingers 20A, 20B. Each dummy electrode finger 20C extends from the opposite bus bar electrode 18A, 18B than the respective electrode finger 20A, 20B with which it is aligned.

It should be appreciated that the acoustic wave resonators 10 illustrated in FIGS. 1A-1C, as well as the other circuit elements illustrated in other figures presented herein, are illustrated in a highly simplified form. The relative dimensions of the different features are not shown to scale. Further, typical acoustic wave resonators would commonly include a far greater number of electrode fingers and reflector fingers than illustrated. Typical acoustic wave resonators or filter elements may also include multiple IDT electrodes sandwiched between the reflector electrodes.

FIG. 2 illustrates a cross-section of the substrate 12 and electrodes 20 that may be utilized in surface acoustic wave devices, for example, as illustrated in any of FIGS. 1A-1C above. The electrodes 20 of FIG. 2 may be any of the IDT electrodes 20A, 20B, the dummy electrodes 20C, or the reflector electrodes 26 of a surface acoustic wave device, for example, as illustrated in any of FIGS. 1A-1C above. The electrodes 20 will, however, be referred to herein as IDT electrodes 20. The IDT electrodes 20 may be multi-layer electrodes including a lower layer 20′ of a first metal and an upper layer 20″ of a second metal that is different from the first metal.

The substrate 12 is a MPS substrate including a support substrate 12A that may be formed of any of Si, quartz, sapphire, or any other suitable material to provide the substrate 12 with a desired amount of mechanical stability. A trap-rich layer 12B formed of, for example, polysilicon is disposed on top of the support substrate 12A and helps to reduce generation of parasitic currents at the upper surface of the support substrate 12A. A layer 12C of a dielectric material, for example, a 600 nm thick layer of SiO₂ is disposed on the upper surface of the trap-rich layer 12B. Layer 12C may be referred to herein as a functional layer. A layer 12D of a piezoelectric material, for example, a 1,000 nm thick layer of lithium tantalate (LiTaO₃) or lithium niobate (LiNbO₃) is disposed on the upper surface of the layer 12C of dielectric material. The IDT electrodes 20 are disposed on the upper surface of the layer 12D of piezoelectric material. The piezoelectric material of layer 12D may exhibit a negative temperature coefficient of frequency. This may be compensated for by the positive temperature coefficient of frequency exhibited by the SiO₂ in the functional layer 12C.

Another example of a substrate structure for a surface acoustic wave device for example, as illustrated in any of FIGS. 1A-1C above is illustrated in FIG. 3. The substrate structure of FIG. 3 is similar to that of FIG. 2, however, the trap-rich layer 12B and functional layer 12C have been removed from beneath the layer 12D of piezoelectric material, although in some embodiments, the trap-rich layer may remain. The surface acoustic wave device structure of FIG. 3 also differs from that of FIG. 2 in that the functional layer 12C is disposed on top of the IDT electrodes 20 and the layer 12D of piezoelectric material. In embodiments in which the functional layer 12C is formed of SiO₂ it may act as a temperature compensation layer for the acoustic wave device. A surface acoustic wave resonator having a structure such as shown in FIG. 3 may thus be referred to as a temperature compensated surface acoustic wave (TCSAW) resonator.

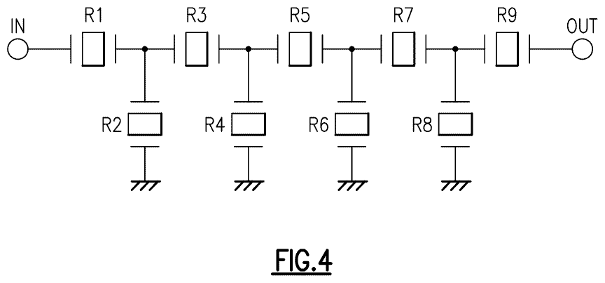

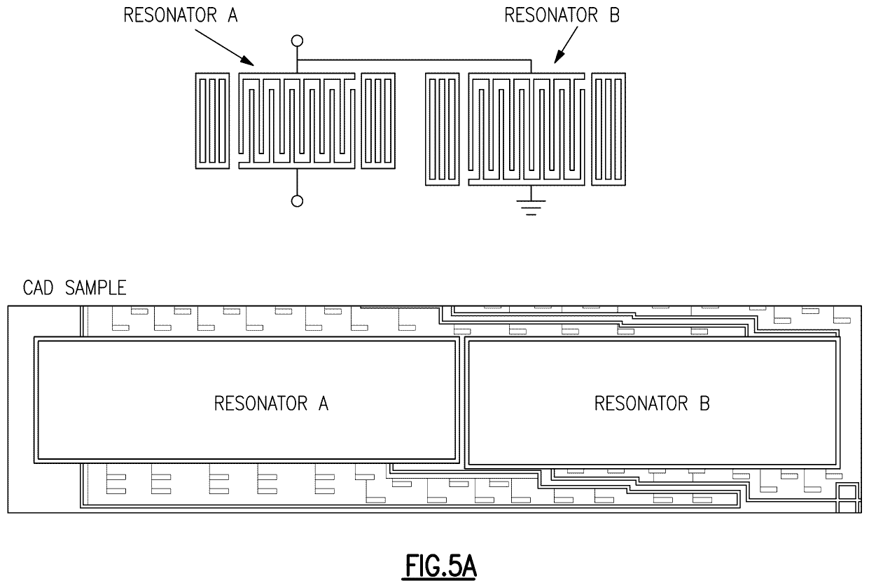

In some embodiments, multiple SAW resonators as disclosed herein may be combined into a filter, for example, a radio frequency (RF) ladder filter such as that schematically illustrated in FIG. 4 and including a plurality of series resonators R1, R3, R5, R7, and R9, and a plurality of parallel resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW devices or resonators, for example, duplexers, baluns, etc., may also be formed including examples of SAW resonators as disclosed herein.

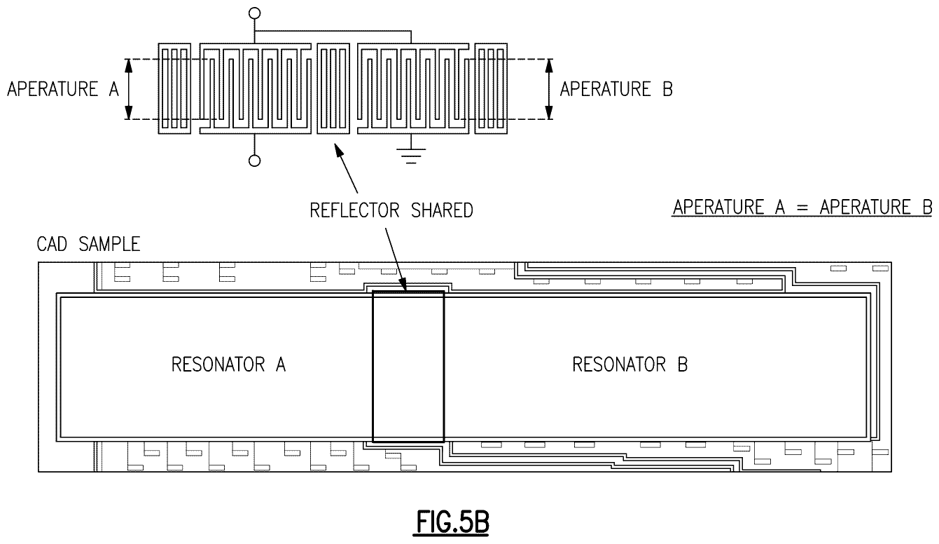

In the physical layout of the SAW resonators of a ladder filter such as illustrated in FIG. 4, two different resonators, for example, two different series resonators, two different parallel resonators, or a series resonator and a parallel resonator may be formed adjacent to one another, for example, as illustrated in FIG. 5A. In some instances it may be possible to rearrange the two adjacent resonators to be closer together and to share a reflector grating disposed between the IDT electrodes of each resonator, for example, as shown in FIG. 5B. This may help to reduce the overall size of the ladder filter and the die on which the filter is formed, which may result in reduced cost per die. In the past, however, design rules limited the features of resonators that could utilize a shared reflector as illustrated in FIG. 5B. For example, the apertures (the length of the area including interdigitated electrode fingers 20A, 20B), and the layer stack, e.g., the thickness of the SiO₂ layers of two resonators utilizing a shared reflector were required to be the same for the two resonators to share a reflector. Aspects and embodiments disclosed herein improve upon these prior design rules to provide for resonators having different structures to utilize a shared reflector.

It should be noted that as the terms are used herein a length direction refers to a direction parallel to the extending direction of the electrode fingers of the disclosed resonators and a width direction is normal to the length direction and parallel to a direction in which main acoustic waves generated in the resonators pass through the resonator structures. A height or thickness direction is normal to a plane defined by the surface of the substrate on which the IDT electrodes and reflectors of the disclosed resonators are disposed.

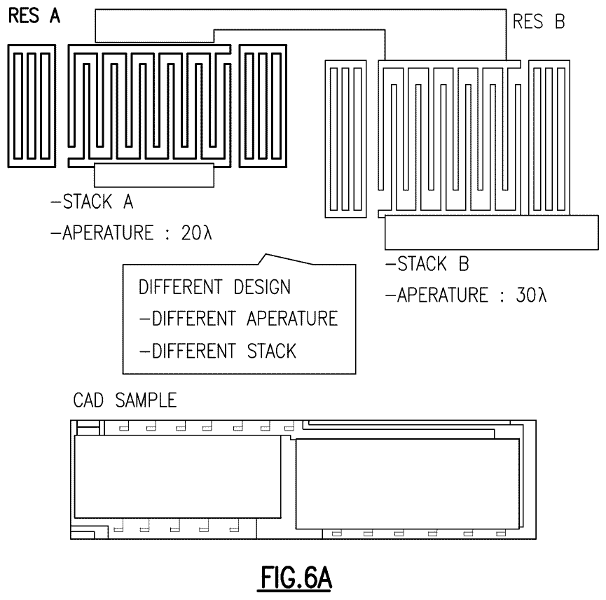

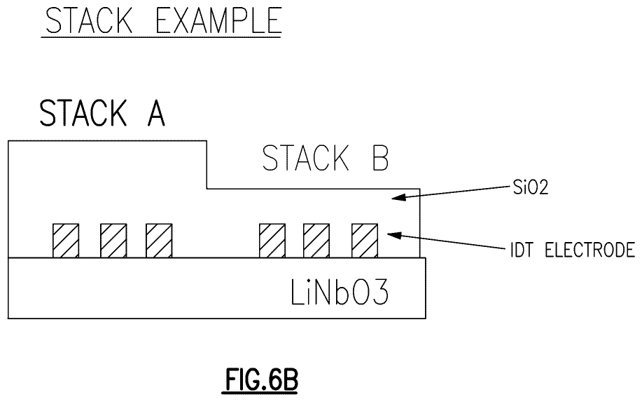

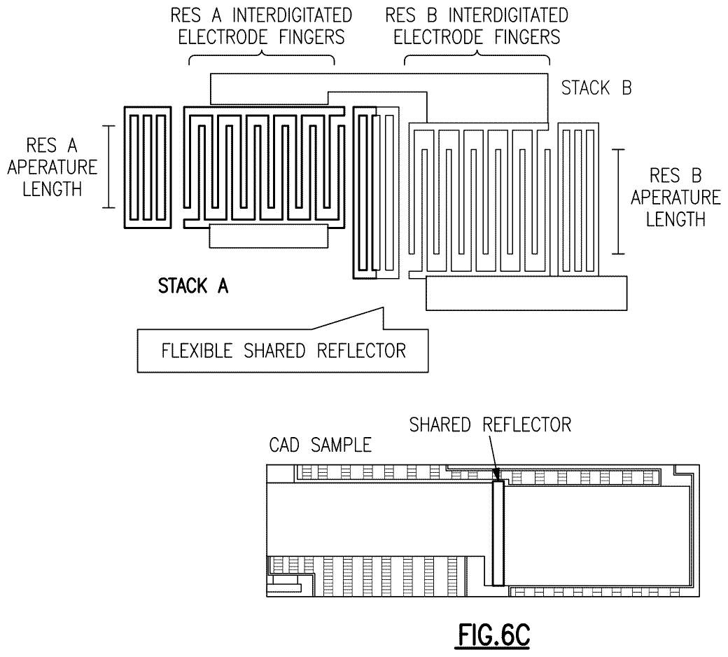

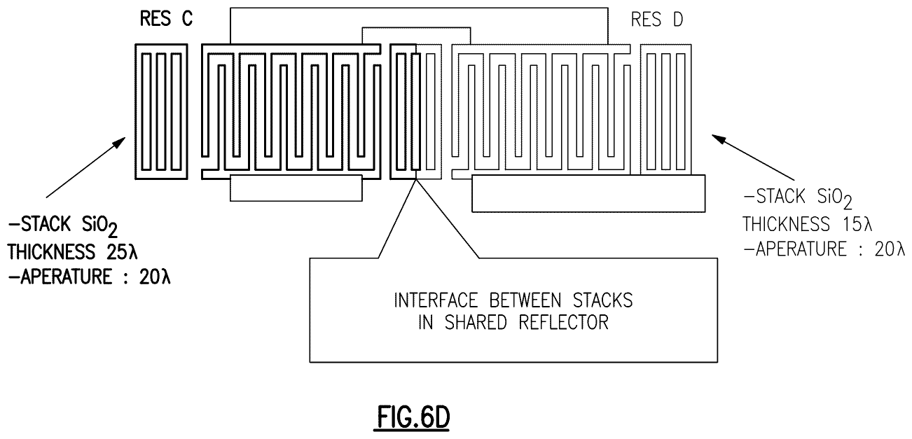

FIG. 6A illustrates two resonators Res A, Res B of a ladder filter that are located close to one another but have different aperture lengths (20 λ for Res A and 30 λ for Res B in FIG. 6A, but these aperture lengths are non-limiting examples) and different SiO₂ layer thicknesses, schematically illustrated in FIG. 6B in which details of the substrate are omitted. Stack A of Res A has a greater SiO₂ thickness than Stack B of Res B. In embodiments in which the two resonators Res A, Res B are formed on multilayer piezoelectric substrates, in addition to or as an alternative to the layers of SiO₂ covering the IDT electrodes being different, the thicknesses of the buried SiO₂ layers (layer 12C of FIG. 2) and/or the layers of piezoelectric material may be different between Res A and Res B. In accordance with prior design rules, these two resonators would not be able to share a reflector because of their structural differences.

The inventors have discovered, however, that a shared reflector could be utilized for resonators with different aperture lengths and stack thicknesses such as those illustrated in FIGS. 6A and 6B. An example of a shared reflector for such different resonators is shown in FIG. 6C. The shared reflector disposed between the interdigitated electrode structures of the two resonators Res A, Res B in FIG. 6C overlaps the apertures of both resonators in a widthwise direction. An upper busbar of the shared reflector is aligned in a widthwise direction with an upper busbar of Res A and a lower busbar of the shared reflector is aligned in a widthwise direction with the lower busbar of Res B. The shared reflector includes regions with different SiO₂ thicknesses. A portion of the shared reflector closest to Res A has an SiO₂ thickness matching the SiO₂ thickness of Stack A of Res A. A portion of the shared reflector closest to Res B has an SiO₂ thickness matching the SiO₂ thickness of Stack B of Res B. The interface between the portions of the shared reflector with the different SiO₂ thicknesses may be located at or approximately at a widthwise center of the shared reflector although in alternative embodiments, this interface may be closer to the Res A or the Res B side of the shared reflector. In the example of FIG. 6C the lengthwise centers of the apertures of Res A and Res B are unaligned in the widthwise direction, however, in other embodiments, for example, as shown in FIG. 6D, the apertures of the two resonators (labelled Res C and Res D in FIG. 6D) may have similar or the same lengths and lengthwise centers that are widthwise aligned although the two resonators may still have different SiO₂ layer thicknesses.

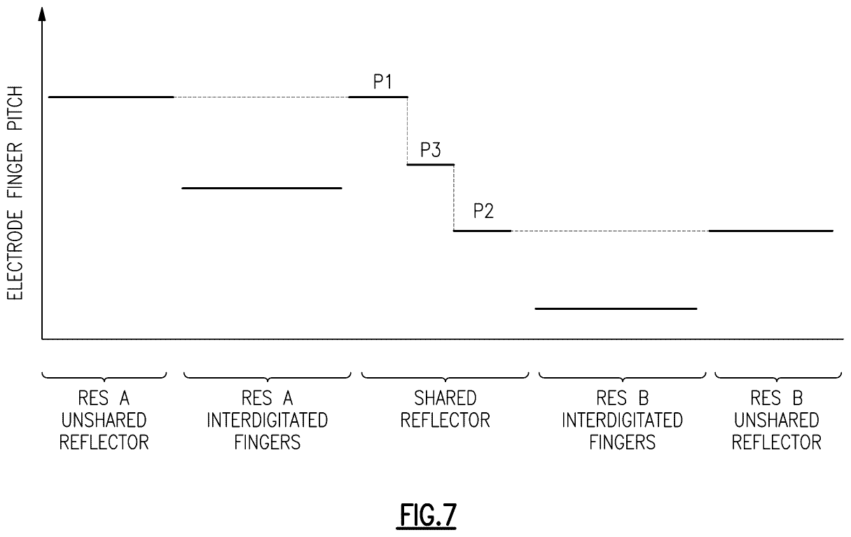

In some embodiments, two resonators having a shared reflector may have different pitches within their interdigitated electrode finger regions and/or in their unshared reflectors. To reduce spurious signals, the pitches of the reflector fingers in the shared reflector on the sides closest to the different resonators may match the pitches of the unshared reflector fingers of the different resonators. For example, as illustrated in FIG. 7, resonators Res A and Res B have a shared reflector between their interdigitated electrode regions and unshared reflectors on sides opposite the shared reflector. The electrode pitches of the reflector fingers in the unshared reflectors of Res A and Res B are different. The shared reflector includes reflector fingers with a pitch P1 on the side of Res A that matches the pitch of the reflector fingers of the unshared reflector of Res A and reflector fingers with a pitch P2 on the side of Res B that match the pitch of the reflector fingers of the unshared reflector of Res B. The shared reflector may further include reflector fingers with a pitch P3 that is between pitches P1 and P2, optionally an average of P1 and P2, disposed between the regions with pitches P1 and P2, respectively. The inclusion of the region in the shared electrode with reflector finger pitch P3 may help reduce generation of spurious signals in the shared reflector.

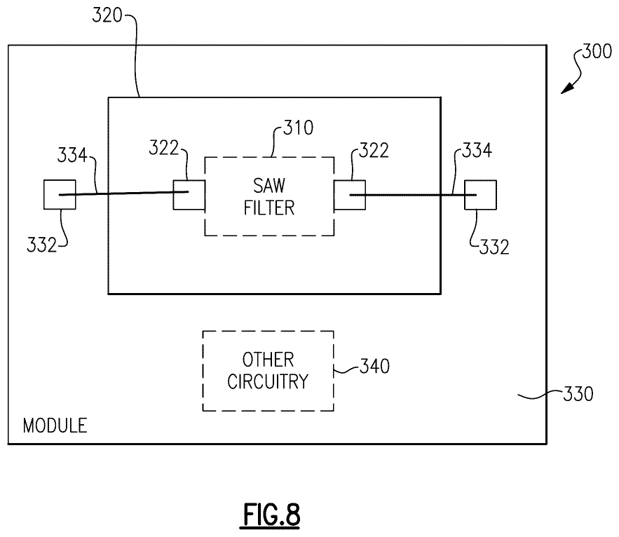

The acoustic wave resonators discussed herein can be implemented in a variety of packaged modules. Some example packaged modules will now be discussed in which any suitable principles and advantages of the packaged acoustic wave resonators discussed herein can be implemented. FIGS. 8, 9, and 10 are schematic block diagrams of illustrative packaged modules and devices according to certain embodiments.

As discussed above, embodiments of the surface acoustic wave elements can be configured as or used in filters, for example. In turn, a surface acoustic wave (SAW) filter using one or more surface acoustic wave elements may be incorporated into and packaged as a module that may ultimately be used in an electronic device, such as a wireless communications device, for example. FIG. 8 is a block diagram illustrating one example of a module 300 including a SAW filter 310. The SAW filter 310 may be implemented on one or more die(s) 320 including one or more connection pads 322. For example, the SAW filter 310 may include a connection pad 322 that corresponds to an input contact for the SAW filter and another connection pad 322 that corresponds to an output contact for the SAW filter. The packaged module 300 includes a packaging substrate 330 that is configured to receive a plurality of components, including the die 320. A plurality of connection pads 332 can be disposed on the packaging substrate 330, and the various connection pads 322 of the SAW filter die 320 can be connected to the connection pads 332 on the packaging substrate 330 via electrical connectors 334, which can be solder bumps or wirebonds, for example, to allow for passing of various signals to and from the SAW filter 310. The module 300 may optionally further include other circuitry die 340, for example, one or more additional filter(s), amplifiers, pre-filters, modulators, demodulators, down converters, and the like, as would be known to one of skill in the art of semiconductor fabrication in view of the disclosure herein. In some embodiments, the module 300 can also include one or more packaging structures to, for example, provide protection and facilitate easier handling of the module 300. Such a packaging structure can include an overmold formed over the packaging substrate 330 and dimensioned to substantially encapsulate the various circuits and components thereon.

Various examples and embodiments of the SAW filter 310 can be used in a wide variety of electronic devices. For example, the SAW filter 310 can be used in an antenna duplexer, which itself can be incorporated into a variety of electronic devices, such as RF front-end modules and communication devices.

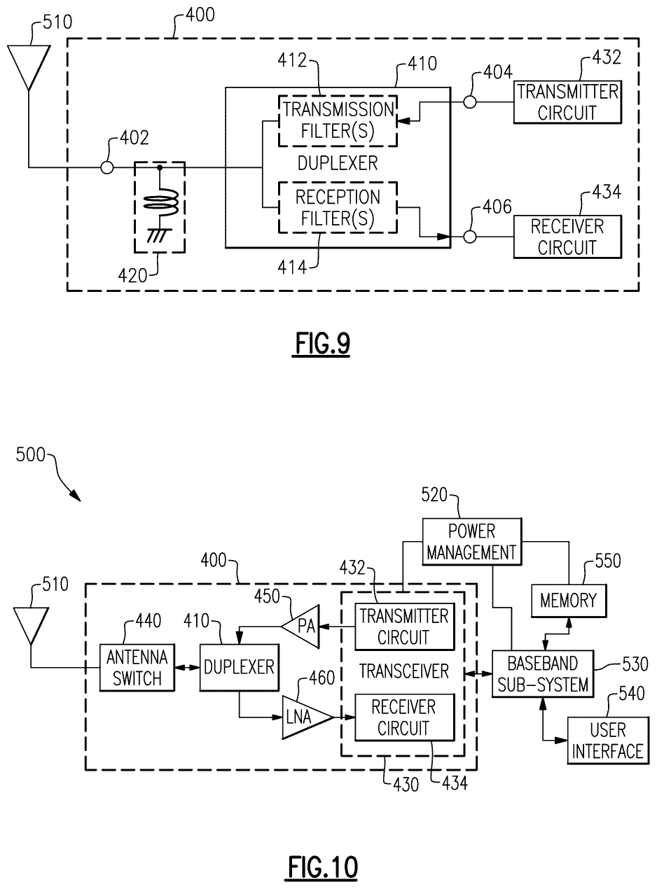

Referring to FIG. 9, there is illustrated a block diagram of one example of a front-end module 400, which may be used in an electronic device such as a wireless communications device (e.g., a mobile phone) for example. The front-end module 400 includes an antenna duplexer 410 having a common node 402, an input node 404, and an output node 406. An antenna 510 is connected to the common node 402.

The antenna duplexer 410 may include one or more transmission filters 412 connected between the input node 404 and the common node 402, and one or more reception filters 414 connected between the common node 402 and the output node 406. The passband(s) of the transmission filter(s) are different from the passband(s) of the reception filters. Examples of the SAW filter 310 can be used to form the transmission filter(s) 412 and/or the reception filter(s) 414. An inductor or other matching component 420 may be connected at the common node 402.

The front-end module 400 further includes a transmitter circuit 432 connected to the input node 404 of the duplexer 410 and a receiver circuit 434 connected to the output node 406 of the duplexer 410. The transmitter circuit 432 can generate signals for transmission via the antenna 510, and the receiver circuit 434 can receive and process signals received via the antenna 510. In some embodiments, the receiver and transmitter circuits are implemented as separate components, as shown in FIG. 9, however in other embodiments these components may be integrated into a common transceiver circuit or module. As will be appreciated by those skilled in the art, the front-end module 400 may include other components that are not illustrated in FIG. 9 including, but not limited to, switches, electromagnetic couplers, amplifiers, processors, and the like.

FIG. 10 is a block diagram of one example of a wireless device 500 including the antenna duplexer 410 shown in FIG. 9. The wireless device 500 can be a cellular phone, smart phone, tablet, modem, communication network or any other portable or non-portable device configured for voice or data communication. The wireless device 500 can receive and transmit signals from the antenna 510. The wireless device includes an embodiment of a front-end module 400 similar to that discussed above with reference to FIG. 9. The front-end module 400 includes the duplexer 410, as discussed above. In the example shown in FIG. 10 the front-end module 400 further includes an antenna switch 440, which can be configured to switch between different frequency bands or modes, such as transmit and receive modes, for example. In the example illustrated in FIG. 10, the antenna switch 440 is positioned between the duplexer 410 and the antenna 510; however, in other examples the duplexer 410 can be positioned between the antenna switch 440 and the antenna 510. In other examples the antenna switch 440 and the duplexer 410 can be integrated into a single component.

The front-end module 400 includes a transceiver 430 that is configured to generate signals for transmission or to process received signals. The transceiver 430 can include the transmitter circuit 432, which can be connected to the input node 404 of the duplexer 410, and the receiver circuit 434, which can be connected to the output node 406 of the duplexer 410, as shown in the example of FIG. 9.

Signals generated for transmission by the transmitter circuit 432 are received by a power amplifier (PA) module 450, which amplifies the generated signals from the transceiver 430. The power amplifier module 450 can include one or more power amplifiers. The power amplifier module 450 can be used to amplify a wide variety of RF or other frequency-band transmission signals. For example, the power amplifier module 450 can receive an enable signal that can be used to pulse the output of the power amplifier to aid in transmitting a wireless local area network (WLAN) signal or any other suitable pulsed signal. The power amplifier module 450 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 450 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 10, the front-end module 400 may further include a low noise amplifier module 460, which amplifies received signals from the antenna 510 and provides the amplified signals to the receiver circuit 434 of the transceiver 430.

The wireless device 500 of FIG. 10 further includes a power management sub-system 520 that is connected to the transceiver 430 and manages the power for the operation of the wireless device 500. The power management system 520 can also control the operation of a baseband sub-system 530 and various other components of the wireless device 500. The power management system 520 can include, or can be connected to, a battery (not shown) that supplies power for the various components of the wireless device 500. The power management system 520 can further include one or more processors or controllers that can control the transmission of signals, for example. In one embodiment, the baseband sub-system 530 is connected to a user interface 540 to facilitate various input and output of voice and/or data provided to and received from the user. The baseband sub-system 530 can also be connected to memory 550 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 600 MHz to 2.7 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave device comprising:
a first surface acoustic wave resonator having a first aperture length and a first stack thickness;
a second surface acoustic wave resonator having a second aperture length and a second stack thickness, one of the first aperture length and second aperture length being different, or the first stack thickness and the second stack thickness being different; and
a common reflector shared by the first surface acoustic wave resonator and the second surface acoustic wave resonator.

2. The surface acoustic wave device of claim 1 wherein lengthwise centers of the apertures of the first surface acoustic wave resonator and the second surface acoustic wave resonator are unaligned in a lengthwise direction.

3. The surface acoustic wave device of claim 2 wherein the common reflector overlaps entireties of the lengths of the apertures of the first surface acoustic wave resonator and the second surface acoustic wave resonator.

4. The surface acoustic wave device of claim 1 wherein the first aperture length and the second aperture length are different and the common reflector overlaps entireties of the lengths of the apertures of the first surface acoustic wave resonator and the second surface acoustic wave resonator.

5. The surface acoustic wave device of claim 1 wherein the first stack of the first surface acoustic wave resonator includes interdigital transducer electrodes covered by a first layer of SiO₂ having a first thickness and the second stack of the second surface acoustic wave resonator includes interdigital transducer electrodes covered by a second layer of SiO₂ having a second thickness different from the first thickness.

6. The surface acoustic wave device of claim 5 wherein the common reflector includes a first portion having the first SiO₂ layer thickness and a second portion having the second SiO₂ layer thickness.

7. The surface acoustic wave device of claim 6 wherein an interface between the first portion and the second portion is located at approximately a widthwise center of the common reflector.

8. The surface acoustic wave device of claim 1 wherein both the first aperture length and second aperture length are different, and the first stack thickness and the second stack thickness are different.

9. The surface acoustic wave device of claim 1 wherein the first surface acoustic wave resonator includes a first unshared reflector and the second surface acoustic wave device includes a second unshared reflector, a first reflector finger pitch of the first unshared reflector being different from a second reflector finger pitch of the second unshared reflector.

10. The surface acoustic wave device of claim 9 wherein the common reflector includes a first region having the first reflector finger pitch and a second region having the second reflector finger pitch.

11. The surface acoustic wave device of claim 10 wherein the common reflector includes a third region having a third reflector finger pitch that is between the first reflector finger pitch and the second reflector finger pitch.

12. The surface acoustic wave device of claim 1 wherein one of the first surface acoustic wave resonator and the second acoustic wave resonator is a series resonator of a ladder filter and the other of the first surface acoustic wave resonator and the second acoustic wave resonator is a parallel resonator of the ladder filter.

13. The surface acoustic wave device of claim 1 wherein each of the first surface acoustic wave resonator and the second acoustic wave resonator is a series resonator of a ladder filter.

14. The surface acoustic wave device of claim 1 wherein each of the first surface acoustic wave resonator and the second acoustic wave resonator is a parallel resonator of a ladder filter.

15. The surface acoustic wave device of claim 1 wherein the first aperture length and the second aperture length are the same, the first surface acoustic wave resonator includes an SiO₂ film with a first thickness, and the second surface acoustic wave resonator includes an SiO₂ film with a second thickness that is different from the first thickness.

16. The surface acoustic wave device of claim 15 wherein the first aperture and the second aperture are aligned in a lengthwise direction.

17. The surface acoustic wave device of claim 1 wherein the first surface acoustic wave resonator and the second surface acoustic wave resonator include multilayer piezoelectric substrates, the multilayer piezoelectric substrate of the first surface acoustic wave resonator having one of a different SiO₂ thickness or a different piezoelectric material thickness than the multilayer piezoelectric substrate of the second surface acoustic wave resonator.

18. A radio frequency filter comprising the surface acoustic wave device of claim 1.

19. An electronics module comprising the radio frequency filter of claim 18.

20. An electronic device including the electronics module of claim 19.
